(19) United States
(12) Patent Application Publication
(10) Pub. No.: US 2011/0291968 A1
(43) Pub. Date: Dec. 1, 2011

(54) TRANSPARENT ELECTRICALLY CONDUCTIVE SUBSTRATE

(76) Inventors: Syozou Kawazoe, Osaka (JP); Hidetomo Nishigaki, Osaka (JP); Takahiko Moriuchi, Osaka (JP)

(21) Appl. No.: 13/115,440

(22) Filed: May 25, 2011

(30) Foreign Application Priority Data
May 27, 2010 (JP) 2010-121213

(51) Int. Cl. H01L 31/0224; G06F 3/041; H05K 13/00; H05K 1/00; H05B 3/02

(52) U.S. Cl. 345/173; 174/258; 219/538; 29/846; 136/256; 178/18.03

(57) ABSTRACT

The present invention provides a transparent electrically conductive substrate having excellent adhesive strength between a transparent electrically conducting film such as ITO and a metal electrode and between a plastic sheet or film substrate and the transparent electrically conducting film, wherein the transparent plastic film substrate, the transparent electrically conducting film, and the metal electrode are formed in this order.

The transparent electrically conductive substrate is provided with a transparent electrically conducting film formed on one or both surfaces of the transparent plastic substrate, and a metal electrode on each transparent electrically conducting film, wherein the transparent electrically conductive substrate has a delamination strength of 0.5 kg/cm or higher between the plastic substrate and each layer.

### BACKGROUND ART

(1) Field of the Invention

The present invention relates to a transparent electrically conductive substrate, in particular to a metal-electrode-equipped transparent electrically conductive substrate comprising a transparent plastic film or sheet, a transparent electrically conducting film formed on the transparent plastic film or sheet, and a metal electrode formed on the transparent electrically conducting film, and a method for producing the same.

(2) Description of the Related Art

Various substrates for optical use are commonly used for members, and the like, of liquid crystal displays, and there is an increasing demand for films for displays, such as CRT, LCD, organic EL, and PDP. These films require an electrode in the form of a film and a circuit formed on a film. In recent years, metal oxide (ITO, ZnO, and other metal oxides) films are used therefor. For example, since displacement is applied to ITO films for touch panels with fingers, and the like, many times, ITO films are required to have very high adhesion to base films. Further, touch panels are used in harsh environments, such as in automobiles and outside; therefore, ITO films are also required to have moisture resistance, heat resistance, light resistance (UV resistance), and the like.

Regarding a transparent electrically conductive film having a transparent metal oxide layer formed on a polyester film base, the adhesive strength between the base and the transparent metal oxide layer is 200 g/cm or less (although there is no problem in tape peeling tests). Due to its weak adhesive strength and insufficient long-term stability, such a film cannot be used in some applications because the transparent electrically conducting layer is peeled off from the base.

To improve the above problem, a film comprising a transparent substrate, a transparent layer (easily adhesive layer) applied on the transparent substrate, and a transparent electrically conducting film formed on the transparent layer has been proposed. However, the adhesive strength thereof is about 300 g/cm, which is still insufficient.

Further, since etching processes are commonly employed to form circuits using ITO films, base films need to have resistance to (acid/alkali) etching. (Peeling of an ITO film from a substrate occurs during etching. To avoid this, improvement of the adhesive strength between a substrate and an ITO film is necessary.)

Polyester films commonly used as base films have poor adhesion to the above-described functional layers. Therefore, it has been generally proposed to laminate an easily adhesive layer made of a polyester resin, an acrylic resin, or an urethane resin on the surface of a polyester film (Patent Literature 1 and 2), and to subject a polyester film to a high-frequency sputter etching treatment in an atmosphere containing at least 50% argon gas (Patent Literature 3). However, the adhesive strength thereof is insufficient.

Further, metal pastes (such as Ag, Au, Cu, and C), which are used as electrodes for the leads of the transparent electrically conducting film described above, have the following problems.

1) Metal pastes have high electrical resistivity because they are obtained by dispersing metal powders in binder resins (insulators). To obtain a metal paste electrode with low electrical resistivity, it is necessary to make improvements, such as increasing the thickness and widening the electrode. The area of the transparent electrically conducting layer to be a display (transparent) portion decreases as the area of the electrode increases. Moreover, these pastes are susceptible to replication. When an electrode is bent, electrode cracking, peeling of an electrode from a transparent electrically conducting layer, and the like, occur; therefore, there are limitations on use for replicating applications. Further, the adhesive strength between ITO and Ag pastes is weak, and thus, lacks long-term reliability. (Although the higher the adhesive strength, the better, the adhesive strength needs to be, in general, 0.5 Kg/cm or more, preferably, 1 Kg/cm or more.)

2) The conduction mechanism of metal paste electrodes is commonly a point contact between metal powders with a size of about a few to several tens of microns. Because of the small contact area, metal paste electrodes have high electrical resistance. Moreover, due to expansion and contraction of binder resins, and the like, metal paste electrodes have drawbacks, such as unstable electrical resistance and poor reliability (poor long-term stability).

3) Metal electrodes are commonly formed by pattern-printing a metal paste on a transparent electrically conducting film by screen printing, and then performing heat-drying for a long time (about 150 to 180° C.×about 30 min). These processes require a substrate to be cut into a single plate, and many processes are necessary due to the batch processing, which also remarkably decreases productivity. Moreover, because of the high-temperature heating, monomers, foreign matter, and the like, bleed out from substrates, resulting in substrate frosting, increase in haze, and the like. This significantly reduces visibility. Further, the high-temperature heating also poses the problem of a shape (size) change of substrates, such as contraction, deformation, and curling, due to thermal contraction of substrates and a difference in thermal contraction between HC (hard coat) layers and substrates. The above-described batch processing involves many manual operations, which lead to the increased occurrence of defective products caused by problems such as staining printed material, breaking or scratching substrates, and adhering foreign matter during operations. Hence, this processing considerably reduces yield.

4) Metal paste electrodes are susceptible to scratches and abrasion. Depressed and repeatedly rubbed portions need to be formed by screen-printing and heat-drying C paste on the metal electrode after printing and drying the metal electrode. This causes further yield reduction and increased costs.

5) The volume resistivity of metal paste electrodes is as high as 3 to 10×10⁻⁵ Ω·cm. When they are used as electrodes, metal pastes are faulty in that, due to the voltage drop, the display size cannot be increased; therefore, it is necessary to take difficult measures, such as increasing the electrode area and leading out many electrodes. Hence, there are also limitations on increasing the display size.

6) Solder, anisotropic conductive connectors, crimp-type connectors (sockets), and the like, are conventionally used for electrical mechanical connection between touch panels and terminal portions of electrical circuits. The poor adhesive strength described above makes the structure complicated. Moreover, as touch panels become more multi-functional, wiring tends to be finer and many wires tend to be used. In addition to the simplification of a connection portion, there is a need for installation of an electrical circuit, an electrical drive component, and the like, on a touch panel sheet. Therefore, it is necessary to increase conductibility and reliability of electrodes, in particular, adhesive strength between a substrate and an ITO film, and between an ITO film and an electrode. (In particular, the adhesive strength of currently used Ag pastes is insufficient. It is said that adhesive strength needs to be 0.5 Kg/cm or more, preferably, 1 Kg/cm or more.)

Low-resistance transparent electrically conducting films having surface resistance of R<50 (Ω/□) are used as electrodes for solar cells, heaters, radio wave shields, and the like. It also has been proposed to make low-resistance transparent electrode bodies with resistance of R<10 (Ω/□) by forming a layer of a metal, such as Cu, Ag, Al or Au, (low resistance, but opaque) on a transparent electrode layer (transparent, but high resistance), and etching the metal layer in the form of a mesh. These products have problems, such as the peeling of a metal layer and a transparent electrically conducting film layer during the etching described above, and poor reliability, due to poor adhesive strength between a transparent electrode layer and a metal layer, and between a substrate and a transparent electrically conducting film.

### CITATION LIST

### Patent Literature

PTL 1: Japanese Unexamined Patent Publication No. 2003-49135
PTL 2: Japanese Unexamined Patent Publication No. 2003-251776
PTL 3: Japanese Unexamined Patent Publication No. 1990-66811

### SUMMARY OF INVENTION

### Technical Problem

The present invention provides a transparent electrically conductive substrate comprising a transparent plastic substrate, a transparent electrically conducting film, and a metal electrode formed in this order. The electrically conductive substrate of the present invention has an excellent adhesive strength between the transparent electrically conducting film, such as ITO, and the metal electrode and between the plastic sheet or film base and the transparent electrically conducting film. The present invention also provides a method for producing the transparent electrically conductive substrate.

### Solution to Problem

Because the adhesive strength between an ITO (metal oxide) film and a metal (in particular, Cu, Al, etc.) film is weak, several methods have been proposed for enhancing the adhesive strength therebetween. Such methods include, for example, forming a metal into a metal oxide to be deposited when metal film deposition is conducted; and forming a metal film on an ITO film and then heating the result at a high temperature (higher than 180° C., the higher the temperature the better effective would be obtained) in oxygen or a vacuum. However, none of these methods satisfactorily improved the adhesive strength, and oxidation of the metal film proceeds, resulting in deterioration of electrical conductivity, oxidation of the electrode, and deterioration in the mechanical strength, adversely affecting the reliability of the substrate.

The inventors conducted various types of research and found that the adhesive strength between an ITO layer and a metal layer can be improved without impairing the electrical conductivity of the metal layer by conducting a plasma treatment under specific conditions.

The inventors also found that the adhesive strength between a plastic film substrate and an ITO thin film can be enhanced by forming an easily adhesive layer having a tensile strength of 64 MPa or higher on a plastic film substrate and then conducting a plasma treatment on the surface of the easily adhesive layer. However, if the plastic substrate has the tensile strength defined above, the formation of an easily adhesive layer is not particularly necessary.

The present invention has been accomplished based on these findings and further research. The present invention provides the following transparent electrically conductive substrates and methods for producing the transparent electrically conductive substrates.

Item 1. A transparent electrically conductive substrate comprising:

a transparent plastic substrate;

a transparent electrically conducting film formed on one or both surfaces of the transparent plastic substrate; and

a metal electrode further formed on each of the transparent electrically conducting film;

the transparent electrically conductive substrate having a delamination strength of 0.5 kg/cm or higher between the plastic substrate and each layer.

Item 2. A transparent electrically conductive substrate comprising:

a transparent plastic substrate;

an easily adhesive layer having a tensile strength of 64 MPa or higher formed on one or both surfaces of the transparent plastic substrate,

a transparent electrically conducting film formed on each easily adhesive layer; and

a metal electrode further formed on each transparent electrically conducting film;

a plasma treatment being performed on the easily adhesive layer and on the transparent electrically conducting film at a degree of vacuum of 8×10⁻⁴ Torr or less.

Item 3. A transparent electrically conductive substrate comprising:

a transparent plastic substrate having a tensile strength of 64 MPa or higher;

a transparent electrically conducting film formed on one or both surfaces of the transparent plastic substrate; and

a metal electrode further formed on each transparent electrically conducting film;

a plasma treatment being performed on the plastic substrate and the transparent electrically conducting film at a degree of vacuum of 8×10⁻⁴ Torr or less.

Item 4. The transparent electrically conductive substrate according to Item 2, wherein the easily adhesive layer has a tensile strength greater than that of the plastic film substrate.

Item 5. The transparent electrically conductive substrate according to any one of Items 2 to 4, wherein the plasma treatment is performed at a degree of vacuum of 4×10⁻⁴ Torr or less.

Item 6. The transparent electrically conductive substrate according to any one of Items 1 to 4, wherein the plastic substrate contains polyester as a resin component.

Item 7. A touch panel comprising any one of the transparent electrically conductive substrates of Items 1 to 6.

Item 8. A solar cell comprising any one of the transparent electrically conductive substrates of Items 1 to 6.

Item 9. An electronic paper comprising any one of the transparent electrically conductive substrates of Items 1 to 6.

Item 10. A transparent heater comprising any one of the transparent electrically conductive substrates of Items 1 to 6.

Item 11. A method for producing a transparent electrically conductive substrate comprising:

forming an easily adhesive layer having a tensile strength of 64 MPa or higher and a transparent electrically conducting film on one or both surfaces of a transparent plastic substrate in this order; and

further forming a metal electrode on the transparent electrically conducting film;

a plasma treatment being performed on the easily adhesive layer prior to the formation of the transparent electrically conducting film, and on the transparent electrically conducting film prior to the formation of the metal electrode at a degree of vacuum of 8×10⁻⁴ Torr or less.

Item 12. A method for producing a transparent electrically conductive substrate comprising:

forming a transparent electrically conducting film on one or both surfaces of a transparent plastic substrate having a tensile strength of 64 MPa or higher; and

further forming a metal electrode on the transparent electrically conducting film;

a plasma treatment being performed on the plastic substrate prior to the formation of the transparent electrically conducting film, and on the transparent electrically conducting film prior to the formation of the metal electrode at a degree of vacuum of 8×10⁻⁴ Torr or less.

### Advantageous Effects of Invention

The transparent electrically conductive substrate of the present invention has a high adhesive strength between the transparent electrically conducting film and the metal electrode and between the plastic substrate and the transparent electrically conducting film. The transparent electrically conductive substrate of the present invention further has excellent characteristics such that the delamination strength between the plastic substrate and each layer is 0.5 kg/cm or higher. Furthermore, the transparent electrically conductive substrate of the present invention has a low surface resistance in the metal electrode, excellent long-term stability in the contact resistance between the transparent electrically conducting film and the electrode, and satisfactory replication property in a 180-degree replication test.

The production method of the present invention allows a transparent electrically conductive substrate to be produced that has excellent adhesive strength between the transparent electrically conducting film and the metal electrode and between the plastic film substrate and the transparent electrically conducting film, wherein the transparent plastic film substrate, the transparent electrically conducting film, and the metal electrode are formed in this order.

### BRIEF DESCRIPTION OF DRAWINGS

FIG. 1 is a cross-sectional view of the transparent electrically conductive substrate according to one embodiment of the present invention.

FIG. 2 is a cross-sectional view of the transparent electrically conductive substrate according to another embodiment of the present invention.

FIG. 3 is a schematic diagram showing the cross section of one example of a resistive film touch panel.

FIG. 4 is a schematic diagram showing the cross section of another example of a resistive film touch panel.

### DESCRIPTION OF EMBODIMENTS

Hereunder, the transparent electrically conductive substrate of the present invention and the method for producing the transparent electrically conductive substrate are explained in detail.

The transparent electrically conductive substrate of the present invention has a transparent electrically conducting film formed on one or both surfaces of a transparent plastic substrate, and further has a metal electrode formed on the surface of the transparent electrically conducting film, wherein the delamination strength between the plastic substrate and each layer is 0.5 kg/cm or higher.

One of the main features of the method for producing the transparent electrically conductive substrate of the present invention is that:

an easily adhesive layer having a tensile strength of 64 MPa or higher and a transparent electrically conducting film are formed on one or both surfaces of a transparent plastic substrate in this order, and a metal electrode is further formed on the transparent electrically conducting film, wherein a plasma treatment is performed on the easily adhesive layer prior to the formation of the transparent electrically conducting film, and on the transparent electrically conducting film prior to the formation of the metal electrode at a degree of vacuum of 8×10⁻⁴ Torr or less.

Another main feature of the method for producing the transparent electrically conductive substrate of the present invention is that:

a transparent electrically conducting film is formed on one or both surfaces of a transparent plastic substrate having a tensile strength of 64 MPa or higher, and a metal electrode is further formed on the transparent electrically conducting film, wherein a plasma treatment is performed on the plastic substrate prior to the formation of the transparent electrically conducting film, and on the transparent electrically conducting film prior to the formation of the metal electrode at a degree of vacuum of 8×10⁻⁴ Torr or less.

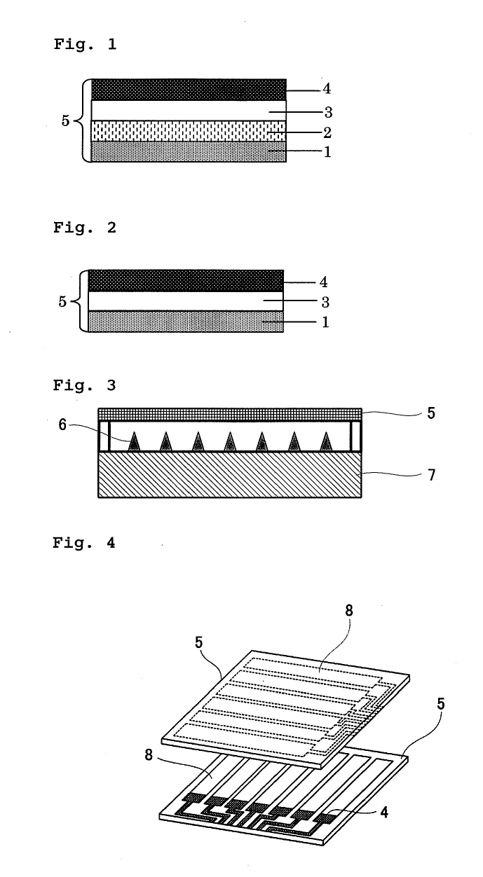

Examples of the transparent electrically conductive substrate of the present invention are shown in FIG. 1 and FIG. 2. FIG. 1 shows a transparent electrically conductive substrate comprising a plastic substrate having a tensile strength of less than 64 MPa. FIG. 2 shows a transparent electrically conductive substrate comprising a plastic substrate having a tensile strength of 64 MPa or higher.

### Plastic Substrate

Various plastic substrates having transparency may be used as the plastic substrate of the present invention. Examples thereof include those containing polyester, polycarbonate, acrylic, polyamide, polyimide, polyolefin, polyvinyl chloride, polyvinylidene chloride, polystyrene, polyvinyl alcohol, polyacrylate, polyarylate, polyphenylene sulfide, or a like as a resin component. Among these, polycarbonate, acrylic, polyester, and the like are particularly preferable. Among polyesters, polyethylene terephthalate is particularly preferable.

The thickness of the plastic substrate is not particularly limited and may be suitably selected depending on the characteristics of the target product; however, it is generally about 6 μm to about 5 mm, and preferably about 20 μm to about 2 mm. The plastic substrate may be in a sheet- or plate-like form, or a film-like form. When a sheet-like formed acrylic, polycarbonate, or the like is used as the plastic substrate, the plastic substrate will have a tensile strength of 64 MPa or higher. This makes the use of an easily adhesive layer unnecessary.

In order to increase the adhesion of the easily adhesive layer, a corona treatment, flame treatment, plasma treatment, or like physical treatment may be applied, as a preliminary treatment, to the surface of the plastic substrate in prior to the formation of the easily adhesive layer on the plastic substrate. A hard coating layer may be formed on the surface that is opposite to the surface on which a transparent electrically conducting film is formed. Prior to the formation of the easily adhesive layer, dust removal or cleaning may be performed, if necessary, by means of solvent cleaning or ultrasonic cleaning.

### Easily Adhesive Layer

The easily adhesive layer in the present invention has a tensile strength (tensile strength at break) (measured according to JIS K 7133: “Method for Determination of Dimensional Change of Plastic Films and Sheets by Heating” of 64 MPa or higher, preferably 68 to 236 MPa. The easily adhesive layer is characterized in that, in particular, when the plastic substrate has a tensile strength of 64 MPa or less, it has a tensile strength greater than that of the plastic substrate. In the present invention, the easily adhesive layer is not an essential component. More specifically, when the plastic substrate has a tensile strength of 64 MPa or higher, providing an easily adhesive layer becomes unnecessary.

Examples of various plastic materials having a tensile strength higher than that of PET (non-oriented) (53-63) and their tensile strength (unit: MPa) are shown below.

Urethane resin (68-88), acrylic resin (76), PC (polycarbonate) (73.6), epoxy resin (70-80), PES (poly ether sulphone) (77-140), PPS (polyphenylene sulfide) (85-211), PAR (polyarylate) (60-70), PEEK (polyetheretherketone) (97-236), LCP (liquid crystal polymer) (127-144), PI (polyimide) (92), PA (polyamide) (73.6), PAI (polyamide-imide) (152), and PEI (polyetherimide) (105). Materials to which glass fiber or carbon is added into the above-mentioned plastic materials in order to enhance the tensile strength, such as GFRTP (glass fiber reinforced thermoplastics) (185) and CFRTP (carbon fiber reinforced thermoplastics) (118-167). Materials suitably comprising the above-mentioned plastic materials in a combined manner so as to enhance the tensile strength.

In order to increase the adhesive strength to the transparent electrically conducting film, the easily adhesive layer may contain a component having a cross-linking structure. A component having a cross-linking structure means a component in which cross-linking agents bind to each other or a cross-linking agent binds to a polymer. Examples of cross-linking agents include epoxy compounds, oxazoline compounds, melamine compounds, isocyanate compounds, and coupling agents.

It is preferable to use a composition for forming easily adhesive layer in combination with a surfactant (e.g., polyoxyethylenealkylphenylether, a sorbitan fatty acid ester, a polyoxyethylene fatty acid ester, and other generally used surfactants) that is chemically inactive to the composition. The amount of the surfactant contained in the composition is preferably 1 to 10 wt %.

The thickness of the easily adhesive layer is not particularly limited, and the composition is applied so that the resulting thickness of the easily adhesive layer becomes generally 0.01 to 0.3 μm, and preferably 0.03 to 0.1 μm. When the thickness of the easily adhesive layer falls within this range, the adhesive strength required can be attained and the resulting easily adhesive layer is free from the occurrence of blocking, an increased Haze value, coloring, image distortion due to optical interference, and the like.

A known method can be employed for forming the easily adhesive layer. For example, roll coating, gravure coating, roll brush coating, spray coating, air knife coating, dip coating, and curtain coating.

When such an easily adhesive layer is present, the adhesive strength between the substrate and the transparent electrically conducting film is ultimately determined by the tensile strength at break of the easily adhesive layer.

### Plasma Treatment (1)

In the present invention, a plasma treatment is performed on the easily adhesive layer or plastic substrate before forming the transparent electrically conducting film thereon at a degree of vacuum of 8×10⁻⁴ Torr or less.

There is no limitation to the gas supplied to the plasma treatment as long as the effect of the invention can be achieved. Examples of usable gases include Ar, Kr, Xe, Ne, He, O₂, O₃, H₂, N₂, N₂O, and NH₃. Among these, H₂, He, N₂, Ne, and like inert gases are preferable. These gases may be used singly or in combination of two or more, and the gas supplied may contain water vapor. The pressure under which the plasma treatment is performed is preferably 4×10⁻⁴ Torr or less. By performing the plasma treatment under such a condition, excellent adhesion between the plastic substrate and the transparent electrically conducting film can be obtained.

The amount of electric discharge during the treatment is generally about 4 to 100 W·sec/cm², and preferably about 10 to 60 W·sec/cm². When the amount of electric discharge falls within this range, the desired adhesive strength can be attained. This prevents the easily adhesive layer or the plastic substrate from yellowing and undesirably increasing the Haze value. When the easily adhesive layer or the plastic substrate is formed of an insulating material like in the present invention, a higher adhesive strength can be attained by RF (high-frequency) discharge plasma than DC (direct current) discharge plasma.

### Transparent Electrically Conducting Film

In the present invention, a transparent electrically conducting film is formed on an easily adhesive layer or a plastic substrate that has undergone a plasma treatment.

There is no limitation on the material for the transparent electrically conducting film as long as it has transparency and conductivity. Examples thereof include indium oxide containing tin oxide, tin oxide containing antimony, and zinc oxide. Particularly preferable is ITO (indium tin oxide), which exhibits excellent transparency and conductivity.

A known technique may be used for forming the transparent electrically conducting film, such as vacuum deposition, sputtering, and ion plating.

The thickness of the transparent electrically conducting film is not particularly limited, and is generally 0.005 to 5 μm, and preferably 0.01 to 0.5 μm. When the thickness falls within this range, the transparent electrically conducting film will have satisfactory conductivity and transparency. Furthermore, such a transparent electrically conducting film will strongly resist cracking caused by expansion and contraction of the substrate, replication, and the like. When the thickness exceeds the above range, curl is observed in the transparent electrically conductive substrate due to the stress of the transparent electrically conducting film, which is undesirable.

### Plasma Treatment (2)

One of the major characteristics of the present invention is that a plasma treatment is performed on the transparent electrically conducting film prior to the formation of a metal electrode at a degree of vacuum of 8×10⁻⁴ Torr or less.

There is no limitation on the gas supplied to the plasma treatment as long as the effect of the invention can be achieved. Examples of usable gases include Ar, Kr, Xe, Ne, He, O₂, O₃, H₂, N₂, N₂O, and NH₃. Among these, H₂, He, N₂, Ne, and like inert gases are preferable. These gases may be used singly or in combination of two or more, and the gas supplied may contain water vapor. The pressure under which the plasma treatment is performed is preferably 4×10⁻⁴ Torr or less. By performing the plasma treatment under such a condition, excellent adhesion between the metal electrode and the transparent electrically conducting film can be obtained.

The amount of electric discharge during the treatment is generally about 8 to 200 W·sec/cm², and preferably about 15 to 100 W·sec/cm². When the amount of electric discharge falls within this range, the desired adhesive strength can be attained. This prevents the transparent electrically conducting film from yellowing. A higher adhesive strength can be attained by an RF (high-frequency) discharge plasma than a DC (direct current) discharge plasma.

### Metal Electrode

There is no limitation on the material for the metal electrode except that it must not be metal paste. Examples thereof include Cu, Ag, Al, Au, Ni, Ni/Cr, and Ti. These metals may be used singly or in a combination of two or more in the form of an alloy. Among these, Cu, Al, and the like are preferable for the reasons that they have high electric conductivity; desirable processability for pattern etching, electroplating, and the like; excellent electrical mechanical connection (soldering, anisotropic conductive connection, and the like) between the electrode and the lead portion of items such as circuits; satisfactory replication property; high thermal conductivity; are inexpensive and the like. In particular, Cu is preferable.

The thickness of the metal electrode is not particularly limited, and is generally 0.001 to 100 μm, and preferably 0.01 to 25 μm.

In the formation of the metal electrode, any known methods may be employed as long as they do not use a metal paste. The metal electrode may be formed by vacuum deposition or sputtering deposition as described in the Examples. Furthermore, the thickness of the film may be increased to improve the conductivity by performing electro/electroless wet plating on the film, if necessary.

If necessary, a layer formed of Ni, Ni/Cr, Cr, Ti, Mo, or like high melting point metal or an oxide thereof may be formed beneath and on the metal electrode to protect the metal electrode (mainly to prevent oxidation).

The transparent electrically conducting film and the metal electrode may be formed either on both surfaces or on one surface of the plastic substrate.

The transparent electrically conductive substrate formed by the production method of the present invention is provided with a transparent electrically conducting film either on both surfaces or on one surface of the transparent plastic film substrate. The transparent electrically conductive substrate further comprises a metal electrode formed on the transparent electrically conducting film. It exhibits excellent adhesive strength such that the delamination strength between the plastic substrate and each layer is 0.5 kg/cm or higher, and preferably 1.0 kg/cm or higher.

Here, the delamination strength between the plastic substrate and each layer is measured as follows. The thickness of the metal electrode film is set to 20 μm (fixed), the metal electrode film is pulled at a fixed peeling speed in such a manner that the film is bent by 90-degree against the substrate, and the peeling strength (90-degree peeling strength) per unit width (1 cm) under such a condition is measured using a load measurement instrument (tensile tester) or the like. The peeling strength thus measured is defined as the delamination strength (adhesive strength F (kg/cm)). At this time, the peeling speed is 5 mm/min. The delamination strength can be measured by the method for measuring the adhesive strength F explained in the Examples.

The transparent electrically conductive substrate of the present invention can be suitably used as a transparent electrode for use in a touch panel, solar cell, transparent heater, electronic paper, and the like. More specifically, the transparent electrically conductive substrate of the present invention can be used as an upper electrode and/or lower electrode in a resistive or capacitive touch panel, and by disposing this touch panel on the front surface of a liquid crystal display, a display apparatus having a touch panel function can be obtained.

FIG. 3 is a schematic diagram showing a widely used resistive, low-reflective touch panel that uses the transparent electrically conductive substrate of the present invention. In FIG. 3, 5 indicates a transparent electrically conductive substrate, 6 indicates a spacer, and 7 indicates ITO glass. When the touch panel is turned on and a user presses an arbitrary location on the transparent electrically conductive substrate with a finger or pen, the transparent electrically conductive substrate comes in contact with the ITO glass at the location that was pressed, and passes an electric current therethrough. This allows the pressed location to be detected using the resistance value from the reference position in each resistive film for the pressed location. The coordinate of the touched location on the panel can be thereby detected, so that an appropriate interface function is achieved. Note that the transparent electrically conductive substrate of the present invention may be used instead of the ITO glass.

FIG. 4 schematically shows a widely used electrode matrix-type resistive film touch panel using the transparent electrically conductive substrate of the present invention. In FIG. 4, 4 indicates a metal electrode, 5 indicates a transparent electrically conductive substrate, and 8 indicates an ITO pattern. When transparent electrically conducting films are formed into rectangular strips and two transparent electrically conductive substrates comprising the transparent electrically conducting films are positioned so that the rectangular strips face each other at a 90-degree angle, the surface can be recognized as a touch panel with isolated portions divided in longitudinal and latitudinal directions.

### EXAMPLES

The present invention is explained in further detail with reference to the Examples. However, the scope of the present invention is not limited to these Examples.

### Evaluation Method

### 1. Adhesive Strength

1) Cross cut test: 100 squares (1 mm×1 mm) were cut with a knife into the surface of a film deposited with Cu and Al and a surface printed with Ag paste. An adhesive tape having a width of 24 mm was adhered to the cross-cut surfaces and then peeled off at a peeling angle of 180 degrees. Thereafter, the number of remaining squares was counted and listed in the table. The peeled portions were also evaluated by visual observation.

2) Adhesive strength F: Cu plating was performed on the surface of metal (Cu, Al) deposited film by electroplating until its thickness became 20 μm.

Thereafter, the Cu plated film was peeled off by being pulled with a load measuring instrument (LTS-50N-S50) manufactured by Minebea Co., Ltd. at a 90-degree angle from the substrate. The peeling strength per unit width (1 cm) under such a condition was measured and defined as the adhesive strength F (kg/cm). Note that the peeling speed in this test was set at 5 mm/min. When the adhesive strength F is 0.5 kg/cm or higher, an adhesive strength that is satisfactory for practical use can be obtained.

The peeled portions between the films were observed to determine the peeling strength between each film.
Method for measuring the adhesive strength of an Ag paste electrode: Ag paste was applied by screen printing on an ITO film formed on a PET substrate, and was then cured (150° C.×30 min) to form an Ag paste electrode having a width of 10 mm and a thickness of 10 μm. Subsequently, the Ag paste electrode surface and a 2-mm-thick SUS plate were attached using double-sided adhesive tape. Using the load measuring instrument, the PET substrate was pulled at a 90-degree angle from the SUS plate and the Ag paste electrode layer. The peeling strength per unit width (1 cm) under such a condition was measured and was defined as the adhesive strength F (kg/cm). Note that the peeling speed in this test was set at 5 mm/min.

The following Examples were conducted using electrodes whose thickness was made to be 10 μm by plating.

### 2. Surface Resistance: R0 (Ω/□), Contact Resistance Between Electrodes Ra (Ω):

1) The surface resistances R0 of the transparent electrically conducting film (ITO) and of the Cu and Al electrode and Ag paste electrode film were measured using a four-terminal resistivity measurement device.

2) The contact resistance Ra between the ITO film and the Cu and Al electrode and Ag paste electrode was measured in the following manner. On both sides of a 5-cm square portion of the ITO transparent conductive layer, a Cu and Al electrode and an Ag paste electrode layer each having a width of about 5 mm and a length of 5 cm were formed to face each other, and the electric resistance R5 between this distance (5 cm), i.e., the surface resistance in the 5-cm square, was measured by a two-terminal method. The surface resistance was expressed as Ra=R5−R0 (Ω).

### 3. Long-Term Stability

The electrodes were kept in a thermostatic oven at 80° C. (250 hours) and in a high-temperature thermostatic oven at 60° C.×90% RH (250 hours), and dipped in 60° C. pure water (10 hours). Thereafter, the deterioration in the electrodes was observed and the electric resistance Ra between the transparent conductive layer and the electrode was measured.

### 4. Replication Property:

The Cu and Al electrode and Ag paste electrode were replicated 180 degrees with the electrode side out, and the electric resistance values before replication (R1) and after replication (R2) of the Cu and Al electrode and Ag paste electrode were measured by the two-terminal method to indicate the rate of increase of the resistance by (R2/R1). Thereafter, the deterioration in the electrodes was evaluated by visual observation.

### EXAMPLES AND COMPARATIVE EXAMPLES

### Example 1

Acrylic resin was applied to the PET side surface of a 125-μm-thick PET film (total light transmittance of about 89%) having a hard coating layer on one surface thereof and then the applied acrylic resin was dried (the acrylic resin was applied by a roll coater method and dried at 110° C.), thereby obtaining an easily adhesive layer (A) having a thickness of about 0.1 μm.

The upper surface of the easily adhesive layer (A) was subjected to a plasma treatment in an inert gas atmosphere, with a degree of vacuum of 4×10⁻⁴ Torr and a plasma amount of 20 W·sec/cm² per unit area.

Subsequently, an ITO film with a surface resistance of 500 (Ω/□) was formed on the coated film (A) by a general sputtering method. The total light transmittance was 88%. The following Examples and Comparative Examples also had a total light transmittance of 88%.

The surface of the ITO film was then subjected to a plasma treatment in an inert gas atmosphere, with a degree of vacuum of 4×10⁻⁴ Torr and a plasma amount of 37 W·sec/cm² per unit area.

Subsequently, Cu was sputter-deposited on the ITO film by a general sputtering method until its thickness became 160 nm to thereby obtain a transparent electrically conductive substrate having a Cu electrode.

The surface resistance of the resulting Cu film was R=0.2 (Ω/□).

### Example 2

A transparent electrically conductive substrate having a Cu electrode was formed in the same manner as in Example 1 except that an easily adhesive layer (B) with a thickness of about 0.05 μm formed of urethane resin was provided on the PET side surface.

### Example 3

A transparent electrically conductive substrate was obtained in the same manner as in Example 1 except that the atmospheric pressure of the plasma treatment performed on the ITO film was set at 8×10⁻⁴ Torr.

### Examples 4 and 5

A transparent electrically conductive substrate having a Cu electrode was obtained in the same manner as in Example 1 except that a plastic film substrate having an HC layer formed on one surface of a PET film having an undercoat layer (an easily adhesive layer) on both surfaces (PET thickness: 125 μm), i.e., U46 (Example 4) and U48 (Example 5) manufactured by Toray Industries, Inc., was respectively used. Both easily adhesive layers were formed of urethane resin, acrylic resin, or a mixture thereof. In Examples 4 and 5, the ITO thin film was formed on the side opposite to the HC layer.

### Example 6

A transparent electrically conductive substrate having an Al electrode was obtained in the same manner as in Example 1 except that Al was used instead of Cu as the metal electrode. The resulting Al deposited film (having a thickness of about 160 nm) had a surface resistance of R=0.3 (Ω/□).

### Comparative Example 1

An ITO film with a surface resistance of 500 (Ω/□) was formed directly (without an acrylic resin layer) on the PET side surface of a 125-μm-thick PET film having a hard coating layer on one surface by conducting sputtering in the same manner as in Example 1. Here, plasma treatment was not performed.

Subsequently, Cu was sputter-deposited on the ITO film (without plasma treatment) by a general sputtering method until the thickness thereof became 160 nm. A transparent electrically conductive substrate having a Cu electrode was thereby obtained.

### Comparative Example 2

An ITO film with a surface resistance of 500 (Ω/□) was formed (without plasma treatment) directly on the PET side surface of a 125-μm-thick PET film having a hard coating layer on one surface by conducting sputtering in the same manner as in Example 1.

Subsequently, the upper surface of the ITO film was subjected to a plasma treatment in an inert gas atmosphere, with a degree of vacuum of 4×10⁻⁴ Torr and a plasma amount of 37 W·sec/cm² per unit area.

Cu was then sputter-deposited on the surface of the ITO film by a general sputtering method until the thickness thereof became 160 nm to thereby obtain a transparent electrically conductive substrate having a Cu electrode.

### Comparative Example 3

### The Same as Example 1 Except that An Easily Adhesive Layer (A) was not Formed

The PET side surface of a 125-μm-thick PET film having a hard coating layer on one surface was subjected to a plasma treatment in an inert gas atmosphere, with a degree of vacuum of 4×10⁻⁴ Torr and a plasma amount of 20 W·sec/cm² per unit area.

An ITO film with a surface resistance of 500 (Ω/□) was formed by conducting sputtering in the same manner as in Example 1.

The upper surface of the ITO film was subjected to a plasma treatment in an inert gas atmosphere, with a degree of vacuum of 4×10⁻⁴ Torr and a plasma amount of 37 W·sec/cm² per unit area.

Subsequently, Cu was sputter-deposited on the ITO film by a general sputtering method until its thickness became 160 nm to thereby obtain a transparent electrically conductive substrate having a Cu electrode.

### Comparative Example 4

A transparent electrically conductive substrate having a Cu electrode was formed in the same manner as in Example 1 except that a plasma treatment was not conducted on the easily adhesive layer (A).

### Comparative Example 5

A transparent electrically conducting film was formed in the same manner as in Comparative Example 1 except that a Cu layer was not provided. Ag paste was applied to the ITO film by screen printing and then cured (150° C.×30 min) to obtain an Ag paste electrode having a width of 10 mm and a thickness of 10 μm.

### Comparative Examples 6 and 7

A transparent electrically conductive substrate was obtained in the same manner as in Example 1 except that the atmospheric pressure of the plasma treatment performed on the ITO film was set at 20×10⁻⁴ in Comparative Example 6 and 40×10⁻⁴ Torr in Comparative Example 7.

### Comparative Examples 8 and 9

A transparent electrically conductive substrate having a Cu electrode was obtained in the same manner as in Examples 4 and 5 except that a plasma treatment was not performed on the easily adhesive layer. In Comparative Examples 8 and 9, the same substrates as those used in Examples 4 and 5 were used, respectively (U46: Comparative Example 8, U48: Comparative Example 9).

### Comparative Example 10

A transparent electrically conductive substrate having an Al electrode was obtained in the same manner as in Comparative Example 1 except that Al was used as the metal electrode instead of Cu.

The transparent electrically conductive substrates obtained in Examples 1 to 6 and Comparative Examples 1 to 10 were examined in terms of adhesive strength, surface resistance, contact resistance between electrodes, long-term stability, and replication property. Table 1 shows the results.

TABLE 1

| | | | | | | Long-term stability of | | | |
|---|---|---|---|---|---|---|---|---|---|
| | | | | | | contact resistance | | | |
| | | | | | Contact | between ITO and | | | |
| | | | | | resistance | electrode Ra (Ω) | | | |
| | | | | | between | | | Dipping | Replication |
| | | | Surface resistance | | electrodes | | | in warm | property |
| | Adhesive strength | | R0 (Ω/□) | | Ra (Ω) | | 60° C. × | water of | (R2/R1) |
| | | Adhesive strength | ITO | Electrode | Between | 80° C. × | 90% RH × | 60° C. × | Between ITO/ |
| | Cross cut test | F (Kg/cm) | layer | film (10 μm) | ITO/electrode | 250 hr | 250 hr | 10 hr | electrode |
| Example 1 | 100/100 | 1.1 (cohesive | 500 | 0.0011 | 0 | 0 | 0 | 0 | 1 |
| | | failure in acrylic | | | | | | | |
| | | resin layer) | | | | | | | |
| Example 2 | 100/100 | 0.6 (cohesive | 500 | 0.0011 | 0 | 0 | 0 | 0 | 1 |
| | | failure in urethane | | | | | | | |
| | | resin layer) | | | | | | | |
| Example 3 | 100/100 | 0.6 (peeling | 500 | — | — | — | — | — | — |
| | | between ITO/Cu) | | | | | | | |
| Example 4 | 100/100 | 1 (cohesive failure | 500 | 0.0011 | 0 | 0 | 0 | 0 | 1 |
| | | in undercoat layer) | | | | | | | |
| Example 5 | 100/100 | 0.5 (cohesive | 500 | 0.0011 | 0 | 0 | 0 | 0 | 1 |
| | | failure in | | | | | | | |
| | | undercoat layer) | | | | | | | |
| Example 6 | 100/100 | 1.1 (cohesive | 500 | 0.0011 | 0 | 0 | 0 | 0 | 1 |
| | | failure in acrylic | | | | | | | |
| | | resin layer) | | | | | | | |
| Comparative | 0/100 | (Peeling between | 500 | — | — | ∞ | ∞ | — | — |
| Example 1 | (peeling | ITO/Cu) F is | | | | | | | |
| | between | unmeasurable because Cu | | | | | | | |
| | ITO/Cu) | plating cannot be | | | | | | | |
| | | performed due to weak | | | | | | | |
| | | adhesive strength. | | | | | | | |
| Comparative | 100/100 | 0.1 (peeling | 500 | — | — | — | — | — | — |
| Example 2 | | between PET/ITO) | | | | | | | |
| Comparative | 100/100 | 0.3 (cohesive | 500 | — | — | — | — | — | — |
| Example 3 | | failure on PET | | | | | | | |
| | | surface) | | | | | | | |
| Comparative | 100/100 | 0.2 (peeling | 500 | — | — | — | — | — | — |
| Example 4 | | between acrylic | | | | | | | |
| | | resin/ITO) | | | | | | | |
| Comparative | — | 0.03 (peeling | 500 | 0.15 | 7 | 15 | 100 | ∞ | 2 (cracking of |
| Example 5 | | between ITO/Ag) | | | | | | (peeling | Ag paste |
| | | | | | | | | of Ag | electrode) |
| | | | | | | | | paste | |
| | | | | | | | | electrode | |
| | | | | | | | | portion) | |
| Comparative | 100/100 | 0.4 (peeling | 500 | — | — | — | — | — | — |
| Example 6 | | between ITO/Cu) | | | | | | | |
| Comparative | 100/100 | 0.2 (peeling | 500 | — | — | — | — | — | — |
| Example 7 | | between ITO/Cu) | | | | | | | |
| Comparative | 100/100 | 0.2 (peeling | 500 | — | — | — | — | — | — |
| Example 8 | | between ITO/Cu) | | | | | | | |
| Comparative | 100/100 | 0.15 (peeling | 500 | — | — | — | — | — | — |
| Example 9 | | between ITO/Cu) | | | | | | | |
| Comparative | 0/100 | (Peeling between | 500 | — | — | ∞ | ∞ | — | — |
| Example 10 | (peeling | ITO/Al) F is | | | | | | | |
| | between | unmeasurable because Cu | | | | | | | |
| | ITO/Al) | plating cannot be | | | | | | | |
| | | performed due to weak | | | | | | | |
| | | adhesive strength. | | | | | | | |

### Evaluation of Etchability

The etchability of the transparent electrically conductive substrate having an electrode obtained in Example 4 was evaluated.

A photoresist film was attached to the Cu electrode, followed by pattern exposure, development, and peeling. The Cu layer was etched into a pattern using Cu-03 produced by Kanto Chemical Co., Inc. (sulfuric acid-based Cu etching solution: liquid temperature of 20° C.). The etching speed at this time was about 110 nm/min. Thereafter, the photoresist film was attached to the ITO layer, followed by pattern exposure, development, and peeling. The ITO layer was etched into a pattern using ITO-07N produced by Kanto Chemical Co., Inc. (oxalic acid-based ITO etching solution: liquid temperature of 50° C.). The etching speed at this time was about 35 nm/min. Excellent pattern formation without peeling of the ITO film was confirmed.

Conventionally known methods for curing electrode paste at high temperatures have various problems such as curling of the substrate, dimensional changes, frosting, Haze value increases, etc. However, when the electrode was formed by the etching method described above, these problems in conventional methods were not observed because it was conducted at a relatively low temperature (50° C. or lower).

The transparent electrically conducting film having an electrode obtained in Comparative Example 1, which employs a conventional method, was evaluated for etchability in the same manner as described above. As a result, the Cu film was entirely peeled off during the Cu etching process. This made it impossible to etch patterns in the Cu film.

### Discussion

### 1) Examples 1 and 2

The results of Examples 1 and 2 indicate the following conclusion. When an easily adhesive layer formed of acrylic resin with a tensile strength of 76 (unit: MPa) or a urethane resin layer with a tensile strength of 68-88 was provided on a polyester film, and an ITO film was then formed on the easily adhesive layer after performing a plasma treatment at an inert gas pressure of 4×10⁻⁴ Torr, and the plasma treatment was also performed on the ITO film under the conditions described above to thereby obtain a Cu electrode, the product of the present invention with the target adhesive strength F of 0.5 kg/cm or higher was obtained.

In the structure of the product of the present invention, the portion having a weak adhesive strength (hereunder shown by F) is the easily adhesive layer (cohesive failure of the easily adhesive layer). It was found that the higher the tensile strength of the easily adhesive layer, the higher the adhesive strength thereof.

It was also found that the resulting Cu electrode had a low surface resistance; a transparent electrically conductive substrate was obtained that exhibited excellent long-term stability in the contact resistance between the ITO and the Cu electrode, satisfactory replication property for 180-degree replication test, and other desirable properties.

### 2) Example 3

The adhesive strength in Example 3 indicates that which was obtained when the atmospheric pressure of the plasma treatment performed on the ITO film was increased to 8×10⁻⁴ Torr. The adhesive strength of Example 3, i.e., 0.6 kg/cm, was slightly lower than that of Example 1; however, the necessary adhesive strength was obtained. It was found that, under such conditions, the resulting product peeled at the portion between the ITO film and Cu.

### 3) Examples 4 and 5

Examples 4 and 5 each used a commercially available product having an undercoat layer (acrylic/urethane resin mixture adhesion treated layer). Both products exhibited improved adhesive strength (0.5 kg/cm or higher) by employing the method of the present invention. It was also found that peeled portion was the portion where cohesive failure occurred in the undercoat layer, the same as in Examples 1 and 2.

### 4) Example 6

In Example 6, an Al electrode was used instead of a Cu electrode (in other respects, production was conducted in the same manner as in Example 1). By employing the method of the present invention, the target adhesive strength was obtained. As with the Cu electrode, the peeled portion was in the acrylic resin layer where cohesive failure occurred.

### 5) Comparative Example 1

Without performing the plasma treatment on the ITO layer, the boundary separation force between the ITO layer and the Cu layer was so weak that peeling occurred in the peeling test using adhesive tape. Therefore, it was not even possible to perform Cu plating in order to measure the adhesive strength. This result indicates that the adhesive strength between the ITO and Cu needs to be improved.

### 6) Comparative Example 2

When the plasma treatment of the present invention was performed on the ITO film (in other respects, production was conducted in the same manner as in Comparative Example 1), the result of the peeling test using adhesive tape was acceptable; however, the adhesive strength was as low as 0.1 kg/cm. In this case, peeling was observed between the PET surface and the ITO, i.e., delamination (boundary separation) occurred. This indicates that improvement in the adhesive strength between the PET surface and the ITO is necessary. The adhesive strength between the ITO film and the Cu layer was improved.

### 7) Comparative Example 3

When an ITO film was formed on the PET surface after performing the plasma treatment of the present invention (in other respects, production was conducted in the same manner as in Comparative Example 2), F was slightly improved to 0.3 kg/cm, which did not meet the target strength (further improvement in F is necessary). Peeling was observed on the PET surface where cohesive failure occurred. This indicates that improvement in the cohesive force of the PET surface is required.

### 8) Comparative Example 4

Acrylic resin was applied on top of the PET as an undercoat to form an easily adhesive layer (in other respects, production was conducted in the same manner as in Comparative Example 2) to thereby form an ITO film. The resulting ITO film had low adhesive strength of F=0.2 kg/cm. Peeling was observed between the acrylic resin and the ITO layer, i.e., boundary separation occurred. This fact indicates that only providing an undercoat layer having strong cohesive force is not sufficient to obtain a desirable adhesive strength, and further improvement in the adhesive strength of the undercoat layer surface is necessary. More specifically, it is necessary to perform a plasma treatment.

### 9) Comparative Example 5

An electrode was formed on the ITO film of Comparative Example 1 without a Cu layer by a known Ag paste printing method. Weak adhesive strength of 0.03 kg/cm was observed between the Ag electrode and the ITO, and the surface resistance of the Ag electrode was higher than that of the Cu electrode. The resulting product had insufficient long-term stability with respect to the contact resistance between the ITO layer and the Ag electrode, and poor 180-degree replication property.

### 10) Comparative Examples 6 and 7

When the pressure of the plasma treatment applied on the ITO was set at 20×10⁻⁴ Torr or 40×10⁻⁴ Torr, the F respectively became 0.4 kg/cm or 0.2 kg/cm. This indicates that when the pressure of the plasma treatment increases, the target F cannot be obtained even if the same method as Example 1 is employed.

### 11) Comparative Examples 8 and 9

Comparative Examples 8 and 9 used commercially available substrates each having an undercoat layer (acrylic/urethane resin mixture easily adhesive layer). When the plasma treatment of the present invention was not performed on the undercoat layer, delamination occurred between the undercoat layer and the ITO, and the F was as weak as 0.2 kg/cm or lower.

### 12) Comparative Example 10

A transparent electrically conductive substrate having an electrode was obtained in the same manner as in Comparative Example 1 except that Al electrode was used instead of the Cu electrode. Delamination between the ITO layer and the Al electrode was observed in the peeling test using adhesive tape. As with the Cu electrode, it was found that it is necessary to perform the plasma treatment of the present invention to improve the F between the Al electrode and the ITO layer.

### Touch Panel

Using the transparent electrically conductive substrates of Examples 1 to 6, a touch panel having a structure as shown in FIG. 3 can be obtained.

### INDUSTRIAL APPLICABILITY

The transparent electrically conductive substrate of the present invention can be used as a transparent touch panel, electronic paper, a transparent electrode for solar cells, a transparent electrostatic/electromagnetic wave shield, a heat ray (infrared ray) shielding film, a transparent electrode for a transparent heater, and the like.

### EXPLANATION OF REFERENCE NUMERALS

1 plastic film substrate
2 Easily adhesive (undercoat) layer
3 ITO thin film
4 metal electrode
5 transparent electrically conductive substrate
6 spacer
7 ITO glass
8 ITO pattern

1. A transparent electrically conductive substrate comprising:
a transparent plastic substrate;
a transparent electrically conducting film formed on one or both surfaces of the transparent plastic substrate; and
a metal electrode on each transparent electrically conducting film;
the transparent electrically conductive substrate having a delamination strength of 0.5 kg/cm or higher between the plastic substrate and each layer.

2. The transparent electrically conductive substrate according to claim 1, which is formed by providing an easily adhesive layer having a tensile strength of 64 MPa or higher on one or both surfaces of the transparent plastic substrate;
forming the transparent electrically conducting film on each easily adhesive layer;
further providing the metal electrode on each transparent electrically conducting film; and
performing a plasma treatment on the easily adhesive layer and on the transparent electrically conducting film at a degree of vacuum of 8×10⁻⁴ Torr or less.

3. The transparent electrically conductive substrate according to claim 1, which is formed by providing the transparent electrically conducting film on one or both surfaces of the transparent plastic substrate having a tensile strength of 64 MPa or higher;
further providing the metal electrode on each transparent electrically conducting film; and
performing a plasma treatment on the plastic substrate and the transparent electrically conducting film at a degree of vacuum of 8×10⁻⁴ Torr or less.

4. The transparent electrically conductive substrate according to claim 2, wherein the easily adhesive layer has a tensile strength greater than that of the plastic film substrate.

5. The transparent electrically conductive substrate according to claim 2, wherein the plasma treatment is performed at a degree of vacuum of 4×10⁻⁴ Torr or less.

6. The transparent electrically conductive substrate according to claim 3, wherein the plasma treatment is performed at a degree of vacuum of 4×10⁻⁴ Torr or less.

7. The transparent electrically conductive substrate according to claim 1, wherein the plastic substrate contains polyester as a resin component.

8. A touch panel comprising the transparent electrically conductive substrate of claim 1.

9. A solar cell comprising the transparent electrically conductive substrate of claim 1.

10. An electronic paper comprising the transparent electrically conductive substrate of claim 1.

11. A transparent heater comprising the transparent electrically conductive substrate of claim 1.

12. A method for producing a transparent electrically conductive substrate comprising:
forming an easily adhesive layer having a tensile strength of 64 MPa or higher and a transparent electrically conducting film on one or both surfaces of a transparent plastic substrate in this order; and
further forming a metal electrode on the transparent plastic substrate;
a plasma treatment being performed on the easily adhesive layer prior to the formation of the transparent electrically conducting film, and on the transparent electrically conducting film prior to the formation of the metal electrode at a degree of vacuum of 8×10⁻⁴ Torr or less.

13. A method for producing a transparent electrically conductive substrate comprising:
forming a transparent electrically conducting film on one or both surfaces of a transparent plastic substrate having a tensile strength of 64 MPa or higher; and
further forming a metal electrode on the transparent electrically conducting film;
a plasma treatment being performed on the plastic substrate prior to the formation of the transparent electrically conducting film, and on the transparent electrically conducting film prior to the formation of the metal electrode at a degree of vacuum of 8×10⁻⁴ Torr or less.
